(19) United States
(12) Patent Application Publication
(10) Pub. No.: US 2014/0172344 A1
(43) Pub. Date: Jun. 19, 2014

(54) METHOD, SYSTEM AND APPARATUS FOR TESTING MULTIPLE IDENTICAL COMPONENTS OF MULTI-COMPONENT INTEGRATED CIRCUITS

(71) Applicant: ADVANCED MICRO DEVICES, INC., Sunnyvale, CA (US)

(72) Inventor: Mark L. Laird, Austin, TX (US)

(73) Assignee: ADVANCED MICRO DEVICES, INC., Sunnyvale, CA (US)

(21) Appl. No.: 13/717,007

(22) Filed: Dec. 17, 2012

(51) Int. Cl. G01R 31/02

(52) U.S. Cl. CPC G01R 31/02
USPC 702/117

(57) ABSTRACT

A method, system and apparatus for testing of multi-component integrated circuits are provided. A multi-component integrated circuit has multiple identical components to be tested. A testing apparatus is provided that is configured to simultaneously apply a test signal to each of a plurality of components of a multi-component integrated circuit to execute a first test on each of the components. A processor receives a group test result for the first test that indicates that one or more of the components failed the first test. The group test result comprises failure data that does not directly indicate whether each component passed or failed the first test. The failure data can be processed to determine which components failed the first test.

### TECHNICAL FIELD

Embodiments of the subject matter described herein relate generally to integrated circuits. More particularly, embodiments of the subject matter relate to a testing of multi-component integrated circuits that include a number of identical components.

### BACKGROUND

When testing the operation of a multi-component IC that includes two or more identical components, two general testing techniques have been developed that can be referred to as sequential testing and parallel testing. One example of a multi-component IC would be a multi-core processor that includes a number of identical cores that need to be tested.

According to a sequential testing technique, a testing apparatus is operated in a “sequential testing mode” to run a series of tests with respect to each component of a multi-component integrated circuit. Each component is individually and sequentially tested by the testing apparatus such that a set or series of tests are run with respect to that component. In response to this set of tests, each component produces test results (e.g., pass or fail) that are specific to that particular component. Thus, one benefit of this sequential testing mode is that it produces test results that are specific for each particular component and can be easily analyzed to identify different problems that might be occurring in each component. However, one drawback of this sequential testing mode is that it is very time consuming since only one component is tested at a time.

According to parallel testing technique, a testing apparatus is operated in a “parallel testing mode” to simultaneously run a series of tests with respect to each component of a multi-component integrated circuit. In other words, each component is individually tested in parallel (or at the same time) by the testing apparatus. In comparison to the sequential testing mode, the parallel testing mode is much faster and more efficient since all of the components are tested at the same time. For each test a “group test result” is generated that indicates whether the components collectively all passed or whether any components failed.

Although each of the components are ideally identical, the test results that are output by each of the components can be different. As such, one drawback of this parallel testing mode is that the group test result of each test only specifies either a pass result or a fail result, but does not include any indication as to which particular component caused the fail result. As such, the group test results can be used to identify which tests were passed and which tests were failed. However, the group test results are not in a format that can be easily used (e.g., by computers, humans, or other entities) to analyze the test results and determine which specific components failed and are not performing as expected.

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### BRIEF SUMMARY OF EMBODIMENTS

Some embodiments provide methods, systems and apparatus for testing multiple identical components of multi-component integrated circuits that can allow multiple components to be tested at the same time to save test time savings, but still allow test result data to be generated on a per component basis so that it can be used for analysis.

In accordance with some of the disclosed embodiments, a computer-implemented method is provided for testing a multi-component integrated circuit that comprises a plurality of components that are to be tested.

A test signal is applied to each of the components at the same time to execute a first test on each of the components such that the plurality of components are tested in parallel as a group.

Based on responses of each of the components to the test signal, it can be determined whether each of the components passed or failed the first test.

A group test result for the first test is then generated that indicates either (a) all of the components passed the first test, or (b) that one or more of the components failed the first test. The group test result does not include information regarding which of the components passed or failed the first test (e.g., does not identify which specific component(s) passed or failed the first test). When one or more of the components failed the first test, the group test result further comprises failure data. The failure data does not directly indicate whether each component passed or failed the first test, but includes information that can be processed to determine which components failed the first test. For instance, in one embodiment, information included in the failure data is processed to generate a component-specific test result for each component that indicates whether that particular component passed or failed the first test.

In some embodiments, a testing apparatus is provided that includes a test signal generator module, a group test processor, and a processor that includes an extraction module. The test signal generator module generates a test signal that is applied to each of the components to execute a first test on each of the components. The group test processor determines whether all of the components passed or failed the first test, and generates a group test result for the first test that indicates that one or more of the components failed the first test when at least one of the components fails the first test. When at least one of the components fails the first test, the group test result comprises failure data that is processed by the extraction module at the processor. Instructions from the extraction module are executed by the processor to process the failure data and determine which components failed the first test.

In some embodiments, a testing system is provided for testing a multi-component integrated circuit that comprises a plurality of components that are to be tested. The testing system includes a testing apparatus, a processor and a memory that is communicatively coupled to the processor. In some implementations, the processor and/or memory can be implemented as part of the testing apparatus.

The testing apparatus can generate a test signal that is applied to each of the components to execute a first test on each of the components; determine, based on responses of each of the components to the test signal, whether each of the components passed or failed the first test; and generate a group test result for the first test that indicates that one or more of the components failed the first test. The group test result comprises failure data. The memory stores an extraction module comprising instructions, that when executed by the processor, cause the processor to process the failure data to determine which components failed the first test.

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures.

FIG. 1 is a block diagram of a testing system in accordance with some of the disclosed embodiments.

FIG. 2 is a flow chart that illustrates a method in accordance with some of the disclosed embodiments.

FIG. 3 is a block diagram that illustrates information that is included in a group test result in accordance with some of the disclosed embodiments.

FIG. 4 is a block diagram that illustrates an example of component-specific test results for each individual component in accordance with some of the disclosed embodiments.

FIG. 5 is a flow chart that illustrates extraction processing in accordance with some of the disclosed embodiments.

FIG. 6 illustrates a block diagram of a computer system for implementing a test system of FIG. 1 in accordance with one exemplary implementation of some of the disclosed embodiments.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

Techniques and technologies may be described herein in terms of functional and/or logical block components and with reference to symbolic representations of operations, processing tasks, and functions that may be performed by various computing components or devices. It should be appreciated that the various block components shown in the figures may be realized by any number of hardware, software, and/or firmware components configured to perform the specified functions. For example, an embodiment of a system or a component may employ various integrated circuit components, e.g., memory elements, digital signal processing elements, logic elements, look-up tables, or the like, which may carry out a variety of functions under the control of one or more microprocessors or other control devices.

For the sake of brevity, conventional techniques related to testing a multi-component integrated circuit, and other functional aspects of the devices and systems (and the individual operating components of the devices and systems) may not be described in detail herein. Furthermore, the connecting lines shown in the various figures contained herein are intended to represent example functional relationships and/or physical couplings between the various elements. It should be noted that many alternative or additional functional relationships or physical connections may be present in an embodiment.

As used herein, a “node” means any internal or external reference point, connection point, junction, signal line, conductive element, or the like, at which a given signal, logic level, voltage, data pattern, current, or quantity is present. Furthermore, two or more nodes may be realized by one physical element (and two or more signals can be multiplexed, modulated, or otherwise distinguished even though received or output at a common node).

The following description refers to elements or nodes or features being “connected” or “coupled” together. As used herein, unless expressly stated otherwise, “coupled” means that one element/node/feature is directly or indirectly joined to (or directly or indirectly communicates with) another element/node/feature, and not necessarily mechanically. Likewise, unless expressly stated otherwise, “connected” means that one element/node/feature is directly joined to (or directly communicates with) another element/node/feature, and not necessarily mechanically. In addition, certain terminology may also be used in the following description for the purpose of reference only, and thus are not intended to be limiting. For example, terms such as “first,” “second,” and other such numerical terms referring to elements or features do not imply a sequence or order unless clearly indicated by the context.

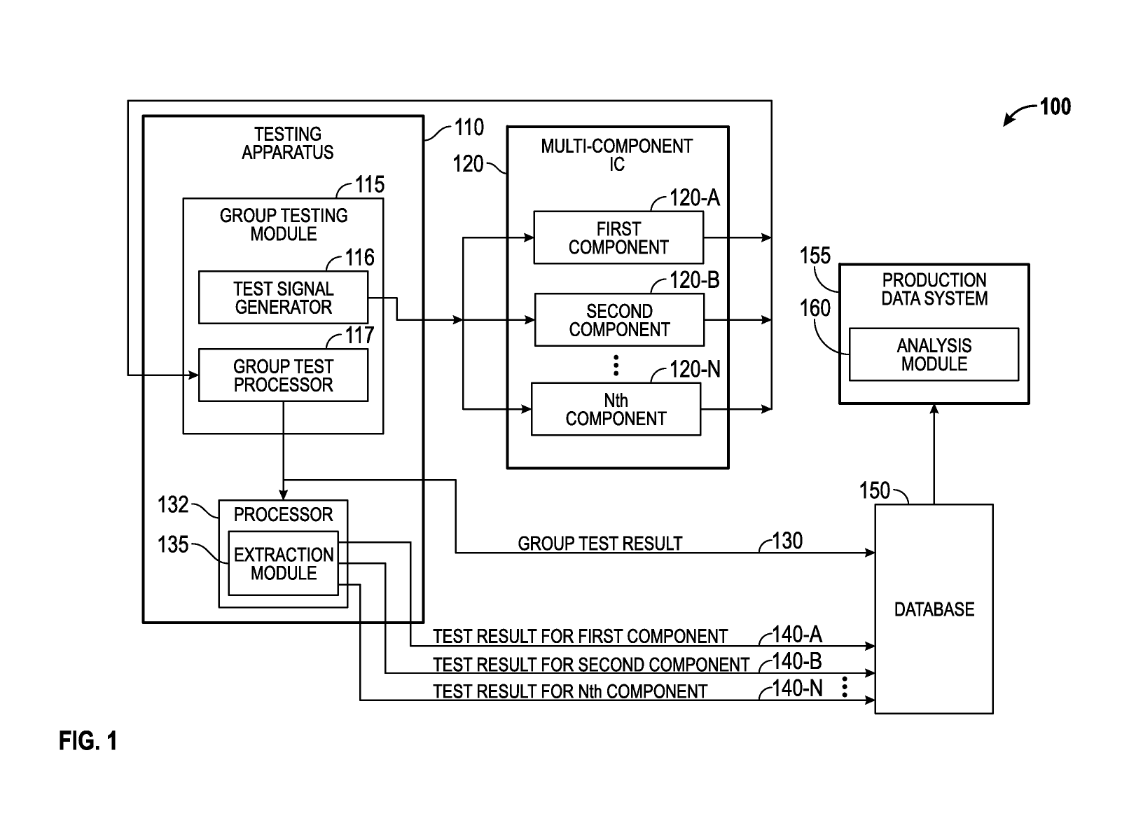

FIG. 1 is a block diagram of a testing system 100 in accordance with some of the disclosed embodiments. The testing system 100 includes a testing apparatus 110 that is operated in a parallel testing mode. FIG. 1 also illustrates a multi-component integrated circuit 120 that is being tested, a database 150 where test results generated by the testing system 100 are stored, and a production data system 155 where test results generated by the testing system 100 can be analyzed; however, these elements are not part of the testing system 100, but are elements that can be used in conjunction with the testing system 100.

The testing apparatus 110 is used to test the multi-component integrated circuit 120. As illustrated, the multi-component integrated circuit 120 includes n substantially identical components 120-A . . . 120-N that are to be tested, where n is an integer that is equal to two or more. The multi-component integrated circuit 120 can be any type of integrated circuit that has n substantially identical components 120-A . . . 120-N that can be tested in parallel or as a group.

As one generic example, the multi-component integrated circuit 120 can be any type of “processing unit” known in the art (e.g., a central processor unit (CPU), a heterogeneous processor unit, an accelerated processing unit (APU), graphics processing unit (GPU), a network processing unit, a security processing unit, a compression processing unit, etc.). As used herein, the term “processing unit” refers to hardware within a computer system, which is designed execute a sequence of stored instructions of a computer program that is stored in some kind of memory by performing the basic arithmetical, logical, and input/output operations of the system. A processor can be, for example, a general-purpose microprocessor. A microprocessor is a multipurpose, programmable device that accepts digital data as input, processes it according to instructions stored in a memory, and provides results as output. A microprocessor can be implemented using one or more large scale integrated circuits that are housed or packaged in a microchip that includes hundreds of connecting pins.

In one particular example, the multi-component integrated circuit 120 can be a multi-core central processing unit (CPU) that has n identical processor cores, where the processor cores are the components 120-A . . . 120-N being tested. However, this example is non-limiting, and it will be appreciated that the testing apparatus 110 can be used to test other types of multi-component integrated circuits 120 that have a plurality of other types of identical components that can be tested by testing apparatus 110 using the same set of tests.

For example, in another implementation, the multi-component integrated circuit 120 can be an accelerated processing unit (APU). An accelerated processing unit (APU) refers to a processing system that includes additional processing capability designed to accelerate one or more types of computations outside of a CPU. This may include a graphics processing unit (GPU) used for general-purpose computing (GPGPU), reconfigurable processing unit, a field-programmable gate array (FPGA), or similar specialized processing system. An APU can also refer to a processing device which integrates a CPU and a GPU on the same die, thus improving data transfer rates between these components while reducing power consumption. APUs can also include video processing and other application-specific accelerators. An APU includes both a CPU that has n identical processor cores and a GPU has n identical shader cores, where either the processor cores or shader cores can be considered as the components 120-A . . . 120-N being tested.

In another implementation, the multi-component integrated circuit 120 can be a graphics processing unit (GPU) also occasionally called visual processing unit (VPU). A GPU can refer to any specialized electronic circuit designed to rapidly manipulate and alter memory in such a way so as to accelerate the building of images in a frame buffer intended for output to a display. GPUs are used in embedded systems, mobile phones, personal computers, workstations, and game consoles. A GPU has n identical shader cores, where the shader cores are the components 120-A . . . 120-N being tested.

The testing apparatus 110 is used to run a series or set of tests (1 . . . x) with respect to each component 120-A . . . 120-N of the multi-component integrated circuit 120. Each component 120-A . . . 120-N is individually tested in parallel (or at the same time) by the testing apparatus 110. As described above, the parallel testing mode is fast and efficient since all of the components 120-A . . . 120-N are tested at the same time.

The testing apparatus 110 includes a test signal generator module 116, a group test processor 117, and a processor 132 that includes an extraction module 135. During testing, the testing apparatus 110 runs the set of tests (1 . . . x) with respect to each component 120-A . . . 120-N. The test signal generator module 116 generates test signal(s) or “stimuli” that are applied to each of the components 120-A . . . 120-N to simultaneously execute the same test on each of the components 120-A . . . 120-N. In other words, the same set of tests (1 . . . x) are run with respect to each component 120-A . . . 120-N. Although each of the components 120-A . . . 120-N are ideally identical, there can be some variations (due to errors in design that cause minor differences, manufacturing variations, etc.). Therefore, in some cases, the test results that are output by each of the components 120-A . . . 120-N in response to each test can be different.

The group test processor 117 determines whether all of the components 120-A . . . 120-N passed or failed each test, and, for each test, generates a group test result 130 that indicates 130-A whether one or more of the components 120-A . . . 120-N passed or failed each particular test. When at least one of the components 120-A . . . 120-N fails a particular test, the group test result 130 comprises failure data 130-B. Thus, in response to information generated during each test, the testing apparatus 110 generates a group test result 130 for that test. Each group test result 130 can be stored in a database 150.

For example, with respect to a first test, a first group test result can be generated that indicates whether (a) all of the components 120-A . . . 120-N passed the first test, or (b) one or more of the components 120-A . . . 120-N failed the first test. Similarly, with respect to a xth test, an xth test result can be generated that indicates whether (a) all of the components 120-A . . . 120-N passed the xth test, or (b) one or more of the components 120-A . . . 120-N failed the xth test. The group test result 130 that is generated for a particular test (that is run by the testing apparatus 110) is not always useful since it does not include information regarding which specific components 120-A . . . 120-N passed or failed that particular test. For example, the group test result 130 for test 1 will indicate either a pass or a fail, but will not identify which specific component(s) 120-A . . . 120-N passed or failed test 1. Similarly, the group test result 130 for test x will indicate either a pass or a fail, but will not identify which specific component(s) 120-A . . . 120-N passed or failed test x. As such, although the group test results 130 that are stored in the database 150 will include pass/fail information for tests 1 through x, that information is not in a format that can be easily used by computers or humans to analyze the test results to determine which tests a particular component is failing, or which components are failing a particular test.

For a group test result that indicates fail, the testing apparatus 110 can include failure data as part of the group test result 130. The failure data includes meta data that can be used to identify which components 120-A . . . 120-N failed each test. Examples of such meta data can include, for example, information that identifies a logical failing address that can be used to determine where a failure is located in a circuit, and used derive which component(s) is/are failing. Such meta data can include, for example, information that identifies failing pin(s) of the IC, information that identifies failing test pattern(s), information that identifies failing cycle count(s), information that identifies failing vector address(es), information that identifies failing vector offset(s), etc. However, the failure data does not include all test information for each component or even a pass/fail result for each component 120-A . . . 120-N.

In accordance with the disclosed embodiments, the extraction module 135 is executed at the processor 132 of the testing apparatus 110. Instructions from the extraction module 135 are executed by the processor 118 to process the failure data 130-B to determine which components 120-A . . . 120-N failed each test. In other words, each group test result 130 that is indicated as a failure can be processed to extract a component-specific test result 140-A . . . 140-N for each component 120-A . . . 120-N. As illustrated in FIG. 1, the extraction module 135 outputs component-specific test results 140-A that are specific to component 120-A, component-specific test results 140-B that are specific to component 120-B, and component-specific test results 140-N that are specific to component 120-N. As will be described in greater detail below, the extraction module 135 can process (e.g., interpret or decode) information included in the failure data 130-B to extract or derive component-specific test results 140-A . . . 140-N for each component 120-A . . . 120-N. Each component-specific test result 140-A . . . 140-N is specific for each particular component 120-A . . . 120-N, and can be generated much faster than in comparison to test results generated using sequential testing since the components are tested in parallel instead of “one at a time” as with sequential testing.

Thus, by implementing the extraction module 135 as a software module within the testing apparatus 110, a self-contained testing apparatus 110 is provided that can process the responses of the components 120 to the group-based test stimuli (as specified in the group test result 130) to generate per component results 140.

In some embodiments, the component-specific test results 140-A . . . 140-N can be stored in the database 150, which can be either part of the test system 100 or external to the test system 100. In some embodiments, the component-specific test results 140-A . . . 140-N for each component 120-A . . . 120-N can be individually loaded into a production data system 155 (that is not part of the testing system 100, but is communicatively coupled to the database 150). The production data system 155 includes an analysis module 160 that can be used to individually analyze each component-specific test result 140-A . . . 140-N for each component 120-A . . . 120-N to determine which components have failed a particular test and are not operating as expected.

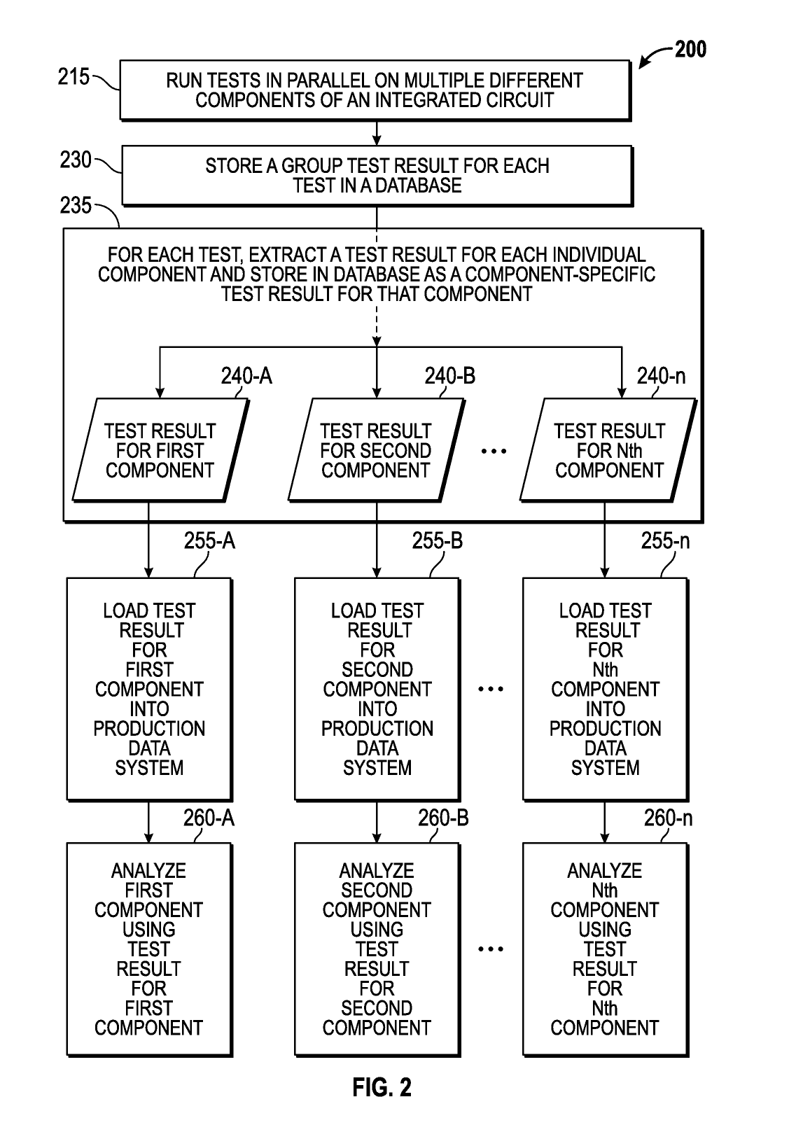

FIG. 2 is a flow chart that illustrates a method 200 in accordance with some of the disclosed embodiments. FIG. 2 will be described below with reference to FIG. 1.

Method 200 begins at 215, where the test signal generator module 116 of the testing apparatus 110 runs a set of tests (1 . . . x) in parallel on multiple different components 120-A . . . 120-N of multi-component integrated circuit 120. For each test, the same stimulus is applied to all components 120 at the same time. Running the tests in parallel on each of the different components 120-A . . . 120-N saves test time involved in generating test data for all of the different components 120-A . . . 120-N. The group test processor 117 determines whether all of the components 120-A . . . 120-N passed or failed the each test, and, for each test, generates a group test result 130 that indicates 130-A whether one or more of the components 120-A . . . 120-N failed that test. When at least one of the components 120-A . . . 120-N fails a particular test, the group test result 130 for that particular test includes failure data 130-B.

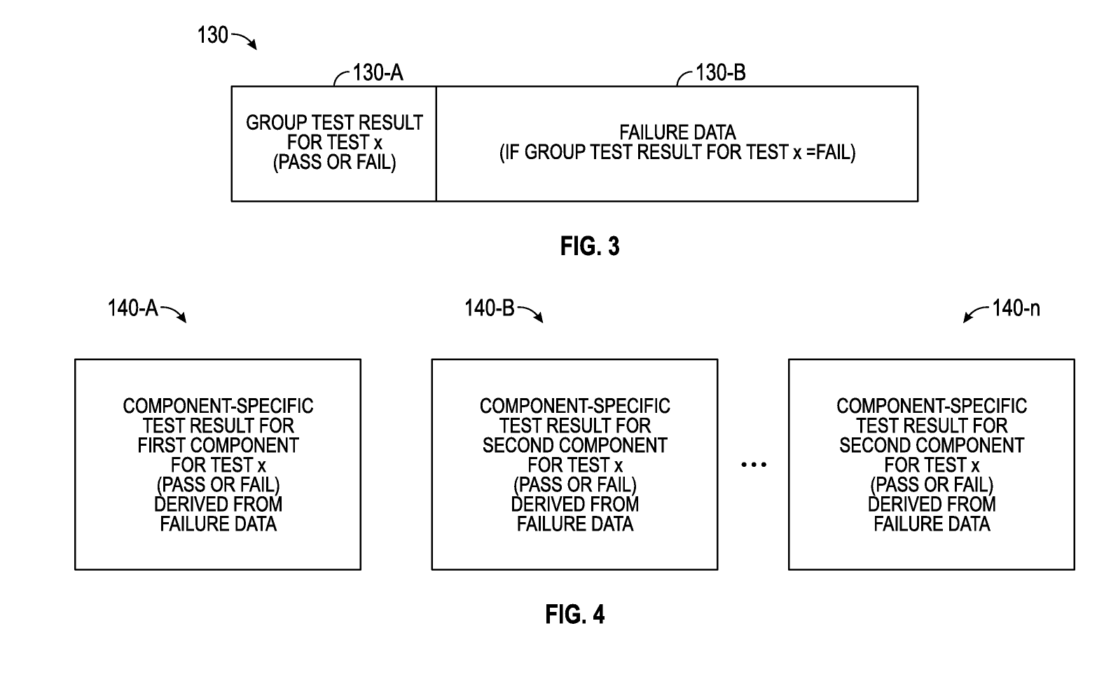

When each test completes, at 230, a group test result for that test is stored in a database 150. FIG. 3 is a block diagram that illustrates information that is included in a group test result 130. The information included in the group test result 130 depends on whether the particular test was a pass or a fail.

When all components 120-A . . . 120-N passed that particular test, the group test result 130 includes information 130-A indicating that the group test result was a pass result.

By contrast, when one or more of the components 120-A . . . 120-N failed that particular test the group test result 130 includes information 130-A indicating that the group test result was a fail result. The information 130-A is not useful by itself for individually analyzing each of the different components 120-A . . . 120-N in isolation, and determining which ones passed or failed a particular test; it only indicates whether all components 120-A . . . 120-N collectively passed or failed that particular test, and provides some additional information (e.g., in a data log for the group test result 130) that is in a format that is not useful for mass data analysis without a bunch of external data processors (i.e., that are external to the testing apparatus 110). As such, this additional information is not in a format that allows it to be analyzed efficiently even though it includes information that can be processed to identify which particular component(s) were the cause of a failed test result. For example, if one component 120-B fails a particular test, then the group test result 130 for that test will indicate failure. At the same time, the details regarding which particular components passed or which particular components failed that particular test are not directly specified in that group test result 130. By contrast, when the group test result 130 is pass, then it can be assumed that all components 120 passed the particular test. However, it is undesirable to implement external data processors to determine which particular components passed or which particular components failed that particular test.

In accordance with the disclosed embodiments, as illustrated in FIG. 3, the group test result 130 not only includes information 130-A indicating that the group test result was a fail result, but also includes failure data 130-B. The failure data 130-B is included as part of the group test result 130 when the test that it relates to was determined to be a fail (i.e., one or more components failed). The failure data 130-B does not include all test information for each component, and does not even include a pass/fail result for each component 120-A . . . 120-N. However, the failure data 130-B does include information that can be processed (e.g., interpreted or decoded) at the extraction module 134 of the testing apparatus 110 to extract or derive component-specific test results 140-A . . . 140-N for each component 120-A . . . 120-N. The information that can be processed at the extraction module 134 can thus be used to determine which components passed or which components failed a particular test. However, this information does not directly indicate whether a particular component passed or failed that particular test.

At 235, instructions of the extraction module 135 can be executed at the processor 132 to process (e.g., interprets or decodes) each of the group test results 130 to extract component-specific test results 140-A . . . 140-N for each individual component, and stores the component-specific test results 140-A . . . 140-N in a database 150. In other words, instructions from the extraction module 135 are executed by the processor 118 to process the failure data 130-B (from each group test result) to determine which components 120-A . . . 120-N failed or passed a particular test.

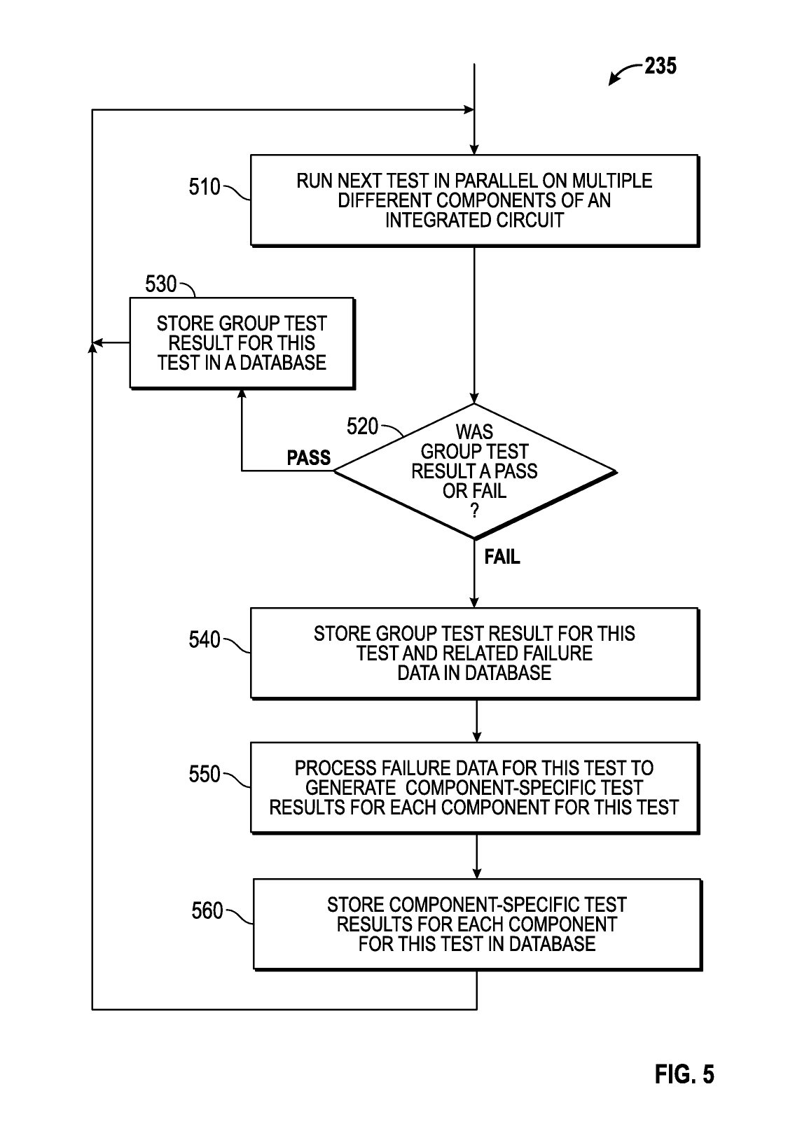

FIG. 4 is a block diagram that illustrates an example of component-specific test results 140-A . . . 140-N for each individual component. The component-specific test results 140-A . . . 140-N include extracted test data 240-A . . . 240-n that is similar to data generated when that particular component is individually tested by itself using sequential testing, but without the delay involved in running each test separately. The extracted test data 240-A . . . 240-n is then in a format that can be directly loaded into the database 150. As such, the component-specific test results 240-A . . . 240-n for each component 120-A . . . 120-N are generated in less time than if each individual component had to be tested separately. One embodiment of the extraction processing will be described below with reference to FIG. 5.

Thus, extraction at 235 produces a component-specific test result 240-A . . . 240-n for each individual component 120-A . . . 120-N. In some embodiments, this component level test data can then be analyzed. At 255-A . . . 255-n, each component-specific test result 240-A . . . 240-n can be individually loaded into a production data system 155, and at 260-A . . . 260-n, the component-specific test results 240-A . . . 240-n for each component 120-A . . . 120-N can be individually analyzed (e.g., by an automated analysis module 160 or by a human) to determine which components are failing and not operating as expected and why.

FIG. 5 is a flow chart that illustrates extraction processing 235 in accordance with some of the disclosed embodiments. FIG. 2 will be described below with reference to FIGS. 1 and 3-4.

The extraction processing 235 begins at 510, where the testing apparatus 110 runs “next” test in a set of tests (1 . . . x) in parallel on multiple different components 120-A . . . 120-N of multi-component integrated circuit 120. During the first iteration of the extraction processing 235, this would be the first test in the set, and during the last iteration of the extraction processing 235, this would be the xth test in the set. As noted above, for each test, the same stimulus is applied to all components 120 at the same time. The test apparatus 110 determines whether each component 120-A . . . 120-N passed or failed this test.

At 520, the testing apparatus 110 determines whether this group test result 130 was a passing result (i.e., all components 120-A . . . 120-N passed) or was a failing result (i.e., one or more of the components 120-A . . . 120-N failed).

When the testing apparatus 110 determines that this group test result 130 was a passing result, at 530, the testing apparatus 110 stores the group test result 130-A in the database 150. In some embodiments, when the testing apparatus 110 determines that this group test result 130 was a passing result, the extraction module 135 processes the group test result 130 to create component specific results 240-A . . . 240-n for each component 120-A . . . 120-n. In this case, all results 240-A . . . 240-n are passes. For instance, the extraction module 135 can try to detect failing group data 130-B, and if this data does not exist, all results 240-A . . . 240-n must be passes since there are only two allowed states (i.e., pass/fail) and there is no failing data 130-B.

When the testing apparatus 110 determines that this group test result 130 was a failing result, at 540, the testing apparatus stores the group test result 130-A in the database 150 along with failure data 130-B associated with the group test result 130. The testing apparatus 110 also passes the group test result 130-A and associated failure data 130-B to the extraction module 135.

At 550, the extraction module 135 processes (e.g., interprets or decodes) the failure data 130-B to generate (e.g., derive or extract) component-specific test results 240-A . . . 240-n for each component 120-A . . . 120-N. Then, at 560, stores the component-specific test results 240-A . . . 240-n for each component 120-A . . . 120-N in the database 150 so that they can be individually analyzed.

Although the embodiments and implementations are described above are illustrated in terms of functional and/or logical block components (or modules) and various processing steps, it should be appreciated that such block components (or modules) may be realized by any number of hardware, software, and/or firmware components configured to perform the specified functions. As used herein the term “component” or “module” can generally refer to a device, a circuit, an electrical component, and/or a software based component for performing a task. As such, those of skill in the art will appreciate that the various illustrative logical blocks, modules, circuits, and algorithm steps described in connection with the embodiments disclosed herein may be implemented as electronic hardware, computer software, or combinations of both.

For example, the various illustrative logical blocks, modules, and circuits described in connection with the embodiments disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such the processor can read information from, and write information to, the storage medium. In the alternative, the storage medium may be integral to the processor. The processor and the storage medium may reside in an ASIC.

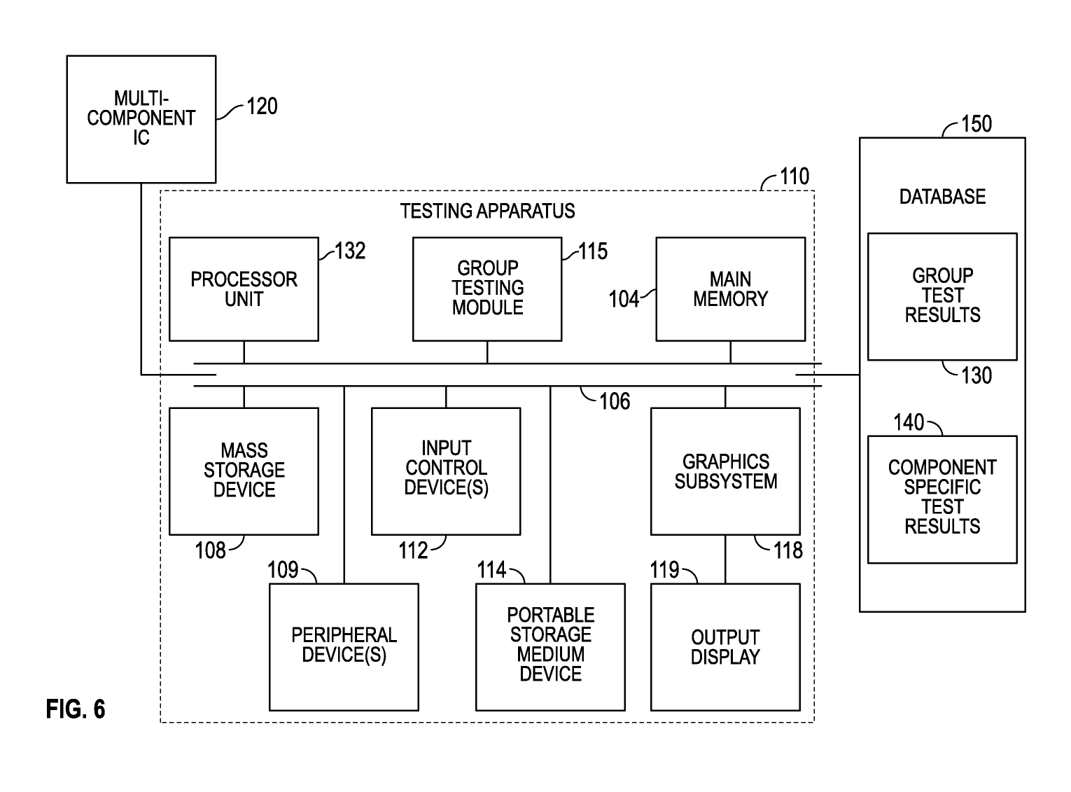

In general, the testing apparatus 110 (illustrated in FIG. 1) can be implemented in any suitable computer based platform known in the art. For example, the system may comprise suitable storage media and one or more dedicated processors or share one or more processors executing/controlling other functions, wherein the employed processor(s) is programmably configured with processor instructions for performing the functions described herein. Suitable circuits may also be developed to execute certain aspects of these functions. One example a computing environment in which the disclosed embodiments may be implemented will now be described below with reference to FIG. 6.

FIG. 6 illustrates a block diagram of a computer system for implementing a test system 100 of FIG. 1. The computer system of FIG. 6 includes one non-limiting implementation of the testing apparatus 110, the multi-component integrated circuit 120 that is being tested, and the database 150 where test results 130, 140 generated by the testing system 100 and extraction module 135 are stored. As above, the testing apparatus 110 is operated in a parallel testing mode.

In this implementation, the testing apparatus 110 includes a processor unit 132, a main memory 104, an interconnect bus 106, a mass storage device 108, peripheral device(s) 109, input control device(s) 112, portable storage drive(s) 114, a group testing module 115 (as described above with reference to FIG. 1), a graphics subsystem 118, and an output display 119.

Processor unit 132 may include a single microprocessor or a plurality of microprocessors configured as a multi-processor system.

Main memory 104 preferably includes banks of dynamic random access memory (DRAM) as well as high-speed cache memory. Main memory 104 stores, in part, instructions and data to be executed by processor unit 132. The main memory 104 (or alternatively the mass storage device 108) stores software modules that include the extraction module 135 of FIG. 1. As explained above, the extraction module 135 of FIG. 1 can be loaded from either memory to the processor unit 132, and then executed at the processor unit 132.

For the purpose of simplicity, the components of testing apparatus 110 are connected via interconnect bus 106. However, testing apparatus 110 may be connected through one or more data transport means. For example, processor unit 132 and main memory 104 may be connected via a local microprocessor bus and mass storage device 108, peripheral device(s) 109, portable storage medium drive(s) 114, and graphic subsystem 118 may be connected via one or more input/output (I/O) buses.

Mass storage device 108, which may be implemented with a magnetic disk drive, an optical disk drive, a solid state device, or an attachment to network storage, is non-volatile storage device for storing data, databases, and instructions, to be used by processor unit 132. In one implementation, the database 150 can be stored at the mass storage device 108. The mass storage device 108 may store any of the software mentioned herein and load it into main memory 104.

Portable storage medium drive 114 operates in conjunction with a portable non-volatile storage medium such as a floppy disk, a compact disk read only memory (CD-ROM), or a digital versatile disk read only memory (DVD-ROM), to input and output data and code to and from the testing apparatus 110. In one embodiment, the software is stored on such a portable medium, and is input to testing apparatus 110 via portable storage medium drive 114.

Peripheral device(s) 109 may include any type of computer support device such as an input/output (I/O) interface, to add additional functionality to testing apparatus 110. For example, peripheral device(s) 109 may include a network interface card to interface computer system 100 to a network.

Input control device(s) 112 provide a portion of the user interface for a testing apparatus 110 user. Input control device(s) 112 may include an alphanumeric keypad for inputting alphanumeric and other key information; and a cursor controlled device such as a mouse, a track pad or stylus; or cursor direction keys.

In order to display textual and graphical information, testing apparatus 110 contains graphic subsystem 114 and output display(s) 119. Output display 119 may include a cathode ray tube (CRT) display, liquid crystal display (LCD), plasma, or light emitting diode (LED) display, etc.

Graphic subsystem 118 receives textual and graphical information and processes the information for output to display 119.

In this particular implementation, the extraction module 135 can be implemented as a software module that can, for example, be stored in memory 104 (or any other memory) and includes computer executable instructions that can be executed at processor unit 132. Similarly, the set of tests (1 . . . x) referred to above can also be stored as a software module that can, for example, be stored in memory 104 (or any other memory) and includes computer executable instructions that can be executed at processor unit 132. Prior to loading in the computer system, the software may reside as encoded information on a computer-readable tangible medium such as a magnetic floppy disk, a magnetic tape, CD-ROM, DVD-ROM, flash memory, or any other suitable computer readable medium.

While at least one exemplary embodiment has been presented in the foregoing detailed description, it should be appreciated that a vast number of variations exist. For example, the disclosed embodiments could be applied to test other multi-component devices that are not multi-component integrated circuits. For example, the disclosed embodiments could be applied to test, for instance, a circuit board with n homogeneous components mounted thereon, where the homogeneous components are the components being tested. In one such implementation, the homogeneous components could be multiple microprocessor die that are mounted on a single circuit board and are the components being tested in parallel. In another implementation, an integrated circuit (e.g., a memory integrated circuit) can be grouped into n identical functional blocks, where the functional blocks are the “components” being tested in parallel. For instance, a one megabyte RAM could be sub-divided into four 256 kilobyte functional blocks, and the four 256 kilobyte functional blocks could be tested in parallel.

It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. A testing system for testing a multi-component integrated circuit that comprises a plurality of components that are to be tested, the testing system comprising:
a testing apparatus, comprising:
a test signal generator module configured to generate a test signal that is applied to each of the components to execute a first test on each of the components;
a group test processor configured to determine whether all of the components passed or failed the first test, and generate a group test result for the first test that indicates that one or more of the components failed the first test, wherein the group test result comprises failure data when at least one of the components fails the first test; and
a processor; and
an extraction module comprising instructions, that when executed by the processor, cause the processor to process the failure data to determine which components failed the first test.

2. A testing system according to claim 1, wherein the extraction module is configured to process information included in the failure data, when the group test result indicates that one or more of the components failed the first test, to generate a component-specific test result for each component,
wherein each component-specific test result is specific to a particular component and indicates whether that particular component passed or failed the first test.

3. A testing system according to claim 1, wherein the group test result does not identify which specific component(s) passed or failed the first test.

4. A testing system according to claim 3, wherein the group test result is not in a format that specifies which components failed the first test.

5. A testing system according to claim 3, wherein the failure data does not directly indicate whether each component passed or failed the first test, and wherein the failure data includes information that can be processed to determine which components failed the first test.

6. A testing system according to claim 5, wherein the information that can be processed to determine which components failed the first test comprises at least:
pin identification numbers of components that failed the first test.

7. A testing system according to claim 1, wherein the multi-component integrated circuit comprises a multi-core central processing unit (CPU) that has a plurality of processor cores, and wherein the plurality of components that are to be tested comprise the processor cores.

8. A testing system according to claim 1, wherein the multi-component integrated circuit comprises an accelerated processing unit (APU), and wherein the plurality of components that are to be tested comprise either processor cores or shader cores.

9. A testing system according to claim 1, wherein the multi-component integrated circuit comprises a graphics processing unit (GPU) comprising a plurality of shader cores, and wherein the plurality of components that are to be tested comprise the shader cores.

10. A testing system according to claim 1, wherein the testing apparatus operates in a parallel testing mode such that the test signal is applied to each of the components at the same time such that the plurality of components are tested in parallel as a group.

11. A testing system according to claim 2, further comprising:
a database that is configured to store the each component-specific test result ; and
a production data system, communicatively coupled to the database, and being configured to individually load each component-specific test result from the database,
wherein the production data system comprises:
a module that is configured to analyze each component-specific test result.

12. A computer-implemented method for testing a multi-component integrated circuit that comprises a plurality of components that are to be tested, the computer-implemented method comprising:
applying a test signal to each of the components at the same time to execute a first test on each of the components such that the plurality of components are tested in parallel as a group;
determining, based on responses of each of the components to the test signal, whether each of the components passed or failed the first test; and
generating a group test result for the first test that indicates either:
that all of the components passed the first test, or
that one or more of the components failed the first test, and wherein the group test result further comprises failure data when one or more of the components failed the first test; and
processing the failure data to determine which components failed the first test.

13. A computer-implemented method according to claim 12, wherein processing comprises:
processing information included in the failure data to generate a component-specific test result for each component, wherein each component-specific test result is specific to a particular component and indicates whether that particular component passed or failed the first test.

14. A computer-implemented method according to claim 12, wherein the failure data does not directly indicate whether each component passed or failed the first test, and wherein the failure data includes information that can be processed to determine which components failed the first test.

15. A computer-implemented method according to claim 14, wherein the information that can be processed to determining which components failed the first test comprises:
pin identification numbers of components that failed the first test.

16. A computer-implemented method according to claim 12, wherein the multi-component integrated circuit comprises a multi-core central processing unit (CPU) that has a plurality of processor cores, and wherein the plurality of components that are to be tested comprise the processor cores.

17. A computer-implemented method according to claim 12, wherein the multi-component integrated circuit comprises an accelerated processing unit (APU), and wherein the plurality of components that are to be tested comprise either processor cores or shader cores.

18. A computer-implemented method according to claim 12, wherein the multi-component integrated circuit comprises a graphics processing unit (GPU) comprising a plurality of shader cores, and wherein the plurality of components that are to be tested comprise the shader cores.

19. A computer-implemented method according to claim 13, further comprising:
storing each component-specific test result in a database; and
loading each component-specific test result from the database into a production data system that is configured to analyze each component-specific test result.

20. A testing apparatus that is configured to simultaneously apply a test signal to each of a plurality of components of a multi-component integrated circuit to execute a first test on each of the components, the testing apparatus comprising:
a processor configured to receive a group test result for the first test that indicates that one or more of the components failed the first test, wherein the group test result comprises failure data that does not directly indicate whether each component passed or failed the first test; and
a memory, coupled to said processor via a bus, wherein the memory includes an extraction module that is configured to store processor-executable instructions that, when executed by the processor, process the failure data to determine which components failed the first test, and generates test results for each of the components that directly indicate whether each of the components failed the first test.
